(19) United States
(12) Patent Application Publication
(10) Pub. No.: US 2026/0255609 A1
(43) Pub. Date: Aug. 27, 2026

(54) MAGNETIZATION ROTATION ELEMENT, MAGNETORESISTANCE EFFECT ELEMENT, MAGNETIC MEMORY, AND METHOD FOR MANUFACTURING MAGNETIZATION ROTATION ELEMENT

(71) Applicant: TDK Corporation, Tokyo (JP)

(72) Inventor: Yugo ISHITANI, Tokyo (JP)

(73) Assignee: TDK Corporation, Tokyo (JP)

(21) Appl. No.: 18/879,090

(22) PCT Filed: Jul. 6, 2022
(86) PCT No.: PCT/JP2022/026788

§ 371 Date: Dec. 26, 2024

(51) Int. Cl. H10B 61/00; H10N 50/01; H10N 50/10

(52) U.S. Cl. CPC H10B 61/20; H10N 50/01; H10N 50/10

(57) ABSTRACT

This magnetization rotation element includes a spin-orbit torque wiring, a first ferromagnetic layer, a first via wiring, and a second via wiring. The first ferromagnetic layer faces at least a part of the spin-orbit torque wiring and is located between the first via wiring and the second via wiring in a lamination direction. The spin-orbit torque wiring has a first region and a second region which do not overlap the first ferromagnetic layer in the lamination direction, and a third region which overlaps the first ferromagnetic layer. The first region has a higher crystallinity than the third region.

### TECHNICAL FIELD

The present invention relates to a magnetization rotation element, a magnetoresistance effect element, a magnetic memory, and a method for manufacturing a magnetization rotation element.

### BACKGROUND ART

Giant magnetoresistance (GMR) elements constituted of a multilayer film having ferromagnetic layers and a nonmagnetic layer, and tunnel magnetoresistance (TMR) elements using an insulating layer (a tunnel barrier layer or a barrier layer) as a nonmagnetic layer are known as magnetoresistance effect elements. Magnetoresistance effect elements can be applied to magnetic sensors, high-frequency components, magnetic heads, and magnetic random access memories (MRAM).

An MRAM is a storage element in which a magnetoresistance effect element is integrated. An MRAM is subjected to reading and writing of data utilizing characteristics of magnetoresistance effect elements whose resistance varies if magnetization directions of two ferromagnetic layers sandwiching a nonmagnetic layer therebetween in a magnetoresistance effect element vary. For example, the magnetization directions of ferromagnetic layers are controlled utilizing a magnetic field generated by a current. In addition, for example, the magnetization directions of ferromagnetic layers are controlled utilizing a spin transfer torque (STT) generated when a current flows in a lamination direction of a magnetoresistance effect element.

When the magnetization directions of ferromagnetic layers are rewritten utilizing an STT, a current is caused to flow in the lamination direction of the magnetoresistance effect element. A writing current may cause deterioration in characteristics of the magnetoresistance effect element.

In recent years, attention has been focused on methods requiring no current to flow in a lamination direction of a magnetoresistance effect element at the time of writing. A writing method utilizing a spin-orbit torque (SOT) is one of the methods (for example, Patent Document 1). An SOT is induced due to a spin current generated by a spin-orbit interaction or a Rashba effect in an interface between different kinds of materials. A current for inducing an SOT into a magnetoresistance effect element flows in a direction intersecting the lamination direction of the magnetoresistance effect element. That is, there is no need for a current to flow in the lamination direction of the magnetoresistance effect element, and thus an extended lifetime of the magnetoresistance effect element is expected.

### CITATION LIST

### Patent Document

Patent Document 1: Japanese Unexamined Patent Application, First Publication No. 2017-216286

### SUMMARY OF INVENTION

### Technical Problem

In magnetoresistance effect elements using a spin-orbit torque (SOT), if a current density of a writing current flowing in a spin-orbit torque wiring reaches or exceeds a predetermined value, magnetization of ferromagnetic layers is reversed. A current density of a writing current causing magnetization of the ferromagnetic layers to be reversed is referred to as a reversal current density. In order to achieve a sufficient reversal current density, the crystallinity of the spin-orbit torque wiring is reduced, and the resistivity of the spin-orbit torque wiring is increased. However, a spin-orbit torque wiring with a high resistivity has problems, such as being likely to generate heat.

The present invention has been made in consideration of the foregoing circumstances, and an object thereof is to provide a magnetization rotation element, a magnetoresistance effect element, and a magnetic memory having high energy efficiency.

### Solution to Problem

In order to resolve the foregoing problems, the present invention provides the following means.
(1) A magnetization rotation element according to a first aspect includes a spin-orbit torque wiring, a first ferromagnetic layer, a first via wiring, and a second via wiring. The first ferromagnetic layer faces at least a part of the spin-orbit torque wiring. The first ferromagnetic layer is located between the first via wiring and the second via wiring in a lamination direction. The spin-orbit torque wiring has a first region, a second region, and a third region. The first region does not overlap the first ferromagnetic layer in the lamination direction and comes into contact with the first via wiring. The second region does not overlap the first ferromagnetic layer in the lamination direction and comes into contact with the second via wiring. The third region overlaps the first ferromagnetic layer in the lamination direction. The first region has a higher crystallinity than the third region.
(2) In the magnetization rotation element according to the aspect, the first via wiring may have a contact region which comes into contact with the spin-orbit torque wiring. The contact region has a higher crystallinity than the third region.
(3) In the magnetization rotation element according to the aspect, a main component of elements constituting the contact region may be the same as a main component of elements constituting the spin-orbit torque wiring.
(4) In the magnetization rotation element according to the aspect, the first region may have a first high crystalline region and a first low crystalline region. In the first region, a proportion of the first high crystalline region may be 50% or higher.
(5) In the magnetization rotation element according to the aspect, the third region may have a second high crystalline region and a second low crystalline region. In the third region, a proportion of the second low crystalline region may be 50% or higher.
(6) A magnetoresistance effect element according to a second aspect includes at least the magnetization rotation element according to the foregoing aspect, a nonmagnetic layer, and a second ferromagnetic layer. The first ferromagnetic layer and the second ferromagnetic layer of the magnetization rotation element sandwich the nonmagnetic layer therebetween.
(7) A magnetic memory according to a third aspect includes the magnetoresistance effect element according to the foregoing aspect.
(8) A method for manufacturing a magnetization rotation element according to a fourth aspect includes a step of connecting a spin-orbit torque wiring and a first via wiring having a contact region with a higher crystallinity than the spin-orbit torque wiring such that the spin-orbit torque wiring and the contact region come into contact with each other, and a step of heating the spin-orbit torque wiring and the first via wiring.
(9) In the method for manufacturing a magnetization rotation element according to the foregoing aspect, a heating temperature may be 200° C. or higher.

### Advantageous Effects of Invention

The magnetization rotation element, the magnetoresistance effect element, and the magnetic memory according to the present disclosure have high energy efficiency.

### BRIEF DESCRIPTION OF DRAWINGS

FIG. 1 is a circuit diagram of a magnetic memory according to a first embodiment.

FIG. 2 is a cross-sectional view of a characteristic part of the magnetic memory according to the first embodiment.

FIG. 3 is a cross-sectional view of a magnetoresistance effect element according to the first embodiment.

FIG. 4 is a plan view of the magnetoresistance effect element according to the first embodiment.

FIG. 5 is an explanatory cross-sectional view of a part of a method for manufacturing the magnetoresistance effect element according to the first embodiment.

FIG. 6 is an explanatory cross-sectional view of another part of the method for manufacturing the magnetoresistance effect element according to the first embodiment.

FIG. 7 is an explanatory cross-sectional view of another part of the method for manufacturing the magnetoresistance effect element according to the first embodiment.

FIG. 8 is a cross-sectional view of a magnetoresistance effect element according to a second embodiment.

FIG. 9 is an explanatory cross-sectional view of a part of a method for manufacturing the magnetoresistance effect element according to the second embodiment.

FIG. 10 is an explanatory cross-sectional view of another part of the method for manufacturing the magnetoresistance effect element according to the second embodiment.

FIG. 11 is a cross-sectional view of a magnetoresistance effect element according to a first modification example.

FIG. 12 is a cross-sectional view of a magnetoresistance effect element according to a second modification example.

FIG. 13 is a cross-sectional view of a magnetization rotation element according to a third embodiment.

### DESCRIPTION OF EMBODIMENTS

Hereinafter, the present embodiment will be described in detail suitably with reference to the drawings. In the drawings used in the following description, in order to make characteristics easy to understand, characteristic portions may be shown in an enlarged manner for the sake of convenience, and dimensional ratios or the like of each constituent element may differ from actual values thereof. Materials, dimensions, and the like shown in the following description are merely exemplary examples. The present invention is not limited thereto and can be suitably changed and performed within a range in which the effects of the present invention are exhibited.

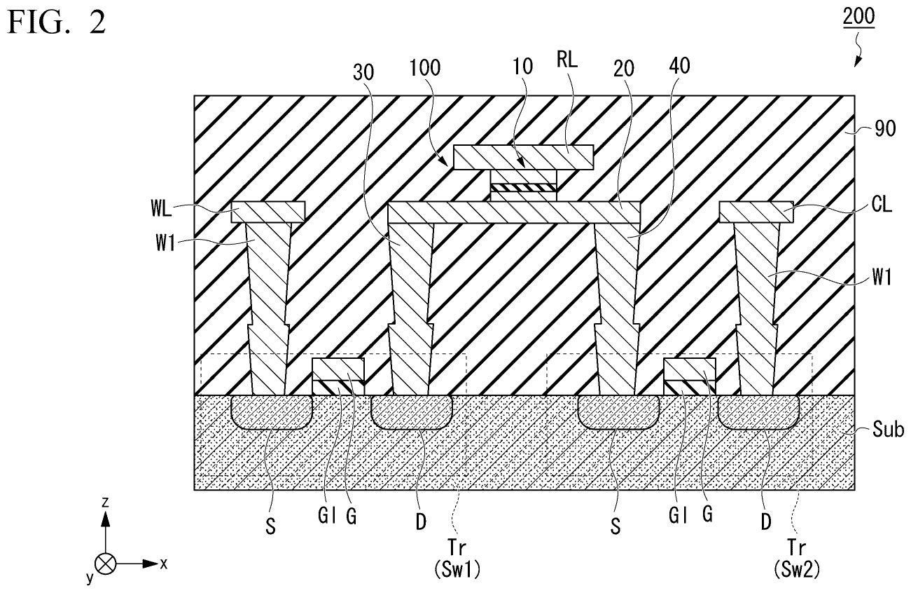

First, directions will be defined. One direction on a surface of a substrate Sub, which will be described below (refer to FIG. 2), will be referred to as an x direction, and a direction orthogonal to the x direction will be referred to as a y direction. For example, the x direction is a longitudinal direction of a spin-orbit torque wiring 20. Az direction is a direction orthogonal to the x direction and the y direction. The z direction is an example of a lamination direction in which layers are laminated. Hereinafter, a positive z direction may be expressed as “upward”, and a negative z direction may be expressed as “downward”. Upward and downward directions do not necessarily coincide with a direction in which gravity is applied.

For example, in this specification, the expression “extending in the x direction” denotes that a dimension in the x direction is larger than a smallest dimension of each of the dimensions in the x direction, the y direction, and the z direction. The same applies to the cases of extending in other directions. In addition, in this specification, the term “connection” is not limited to a case of being physically connected. For example, the term “connection” is not limited to a case in which two layers are physically in contact with each other, and it also includes a case in which two layers are connected to each other with another layer sandwiched therebetween. In addition, the term “connection” also includes a case in which two members are electrically connected to each other. In addition, in this specification, the term “connection” also includes electrical connection. In addition, in this specification, the term “facing” refers to a relationship between two layers facing each other, and the two layers may be in contact with each other or may face each other with another layer sandwiched therebetween.

### First Embodiment

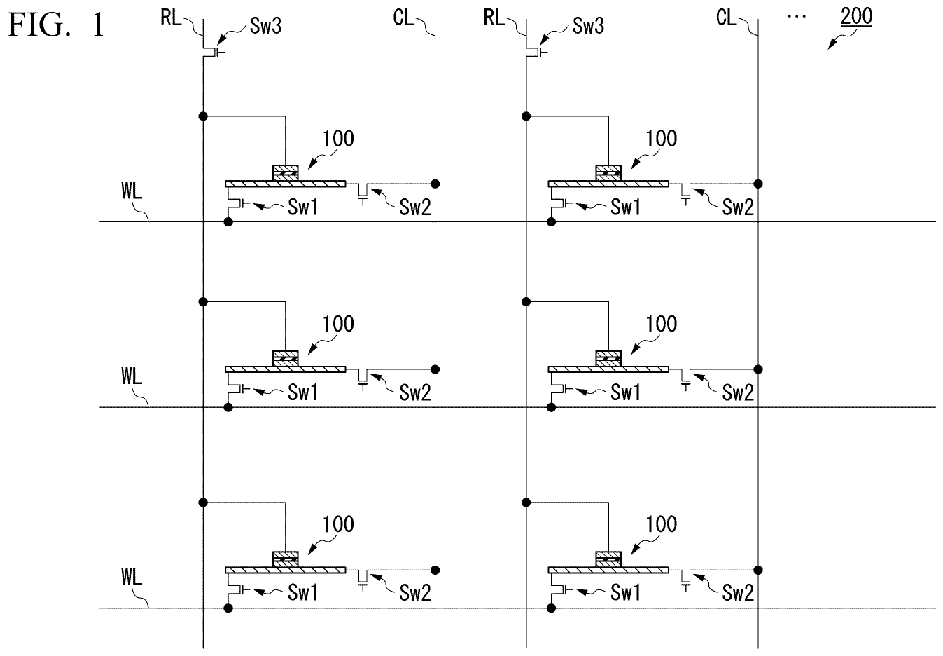

FIG. 1 is a view of a constitution of a magnetic memory 200 according to a first embodiment. The magnetic memory 200 includes a plurality of magnetoresistance effect elements 100, a plurality of writing wirings WL, a plurality of common wirings CL, a plurality of reading wirings RL, a plurality of first switching elements Sw1, a plurality of second switching elements Sw2, and a plurality of third switching elements Sw3. For example, in the magnetic memory 200, the magnetoresistance effect elements 100 are arrayed in a matrix shape.

Each of the writing wirings WL electrically connects a power source to one or more magnetoresistance effect elements 100. Each of the common wirings CL is a wiring used at times of both writing and reading data. Each of the common wirings CL electrically connects a reference electric potential to one or more magnetoresistance effect elements 100. For example, the reference electric potential is a ground potential. The common wiring CL may be provided in each of the plurality of magnetoresistance effect elements 100 or may be provided across the plurality of magnetoresistance effect elements 100. Each of the reading wirings RL electrically connects the power source to one or more magnetoresistance effect elements 100. The power source is connected to the magnetic memory 200 when in use.

Each of the magnetoresistance effect elements 100 is electrically connected to one of the first switching element Sw1, the second switching element Sw2, and the third switching element Sw3. The first switching element Sw1 is connected between the magnetoresistance effect element 100 and the writing wiring WL. The second switching element Sw2 is connected between the magnetoresistance effect element 100 and the common wiring CL. The third switching element Sw3 is connected to the reading wiring RL across the plurality of magnetoresistance effect elements 100.

If a predetermined first switching element Sw1 and a predetermined second switching element Sw2 are turned on, a writing current flows between the writing wiring WL and the common wiring CL connected to a predetermined magnetoresistance effect element 100. Due to a writing current flowing therethrough, data is written in the predetermined magnetoresistance effect element 100. If a predetermined second switching element Sw2 and a predetermined third switching element Sw3 are turned on, a reading current flows between the common wiring CL and the reading wiring RL connected to a predetermined magnetoresistance effect element 100. Due to a reading current flowing therethrough, data is read from the predetermined magnetoresistance effect element 100.

The first switching elements Sw1, the second switching elements Sw2, and the third switching elements Sw3 are elements for controlling a flow of a current. For example, the first switching elements Sw1, the second switching elements Sw2, and the third switching elements Sw3 are transistors, elements such as ovonic threshold switches (OTS) utilizing phase change in a crystal layer, elements such as metal insulator transfer (MIT) switches utilizing variation in a band structure, elements such as Zener diodes and avalanche diodes utilizing a breakdown voltage, or elements whose conductivity varies in accordance with variation in atom positions.

In the magnetic memory 200 shown in FIG. 1, the magnetoresistance effect elements 100 connected to the same reading wiring RL share the third switching element Sw3. The third switching element Sw3 may be provided in each of the magnetoresistance effect elements 100. In addition, the third switching element Sw3 may be provided in each of the magnetoresistance effect elements 100, and the first switching element Sw1 or the second switching element Sw2 may be shared by the magnetoresistance effect elements 100 connected to the same wiring.

FIG. 2 is a cross-sectional view of a characteristic part of the magnetic memory 200 according to the first embodiment. FIG. 2 is a cross section of the magnetoresistance effect element 100 cut along an xz plane passing through the center of the width of the spin-orbit torque wiring 20 (which will be described below) in the y direction.

The first switching element Sw1 and the second switching element Sw2 shown in FIG. 2 are transistors Tr. The third switching element Sw3 is electrically connected to the reading wiring RL and is located, for example, at a different position in the y direction in FIG. 2. For example, the transistors Tr are field effect transistors and have a gate electrode G, a gate insulating film GI, and a source S and a drain D formed on the substrate Sub. The source S and the drain D are prearranged depending on the flowing direction of a current, and these are the same regions. The positional relationship between the source S and the drain D may be reversed. For example, the substrate Sub is a semiconductor substrate.

The transistors Tr and the magnetoresistance effect elements 100 are electrically connected via first via wiring 30 and second via wiring 40. In addition, transistors Tr is connected to the writing wiring WL or the common wiring CL via a via wiring W1. For example, each of the first via wirings 30, the second via wirings 40, and the via wirings W1 extends in the z direction. Each of the first via wirings 30, the second via wirings 40, and the via wirings W1 may be a wiring in which a plurality of columnar bodies are laminated. Each of the first via wirings 30, the second via wirings 40, and the via wirings W1 includes a conductive material.

Areas around the magnetoresistance effect elements 100 and the transistors Tr are covered by an insulating layer 90. The insulating layer 90 is an insulating layer insulating wirings, such as multilayer wirings, and elements from each other. For example, the insulating layer 90 is made of silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), magnesium oxide (MgO), aluminum nitride (AlN), or the like.

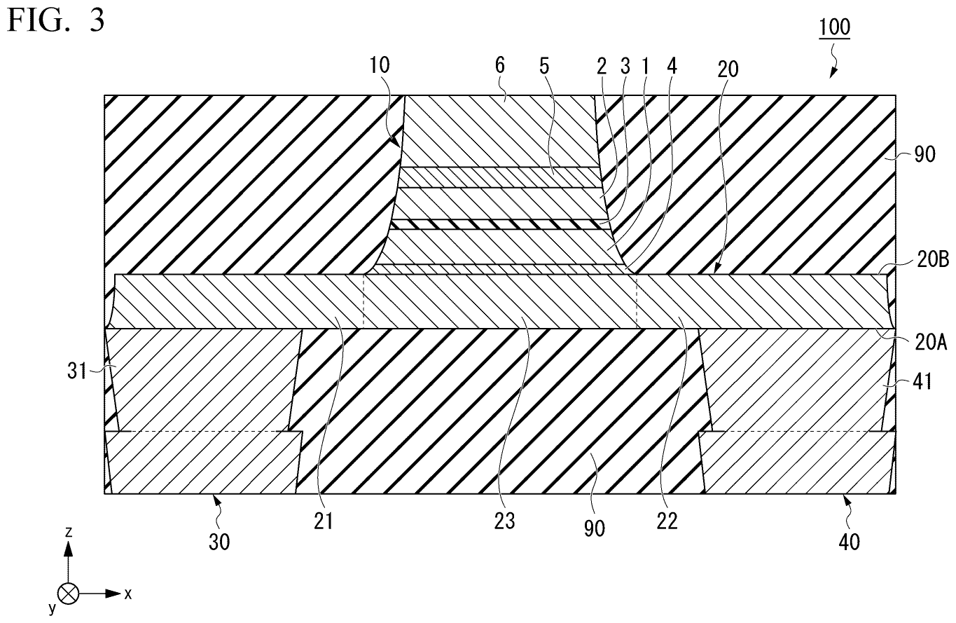

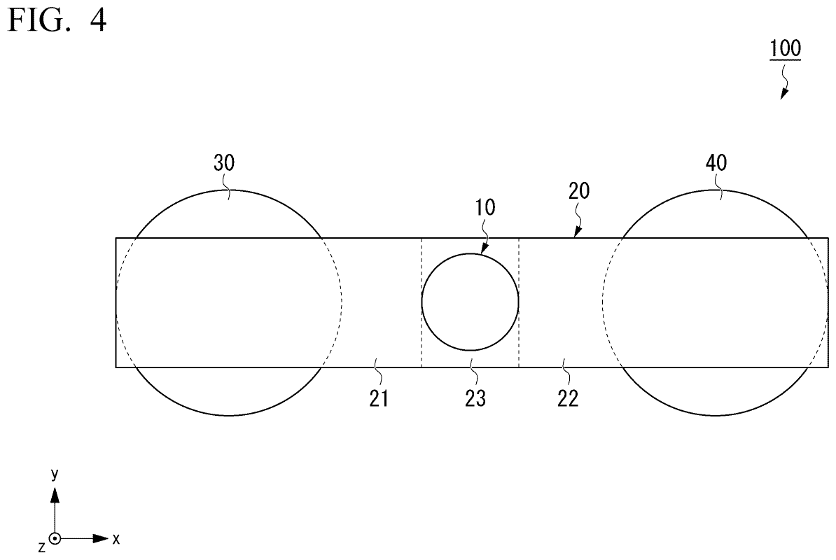

FIG. 3 is a cross-sectional view of the magnetoresistance effect element 100. FIG. 3 is a cross section of the magnetoresistance effect element 100 cut along an xz plane passing through the center of the width of the spin-orbit torque wiring 20 in the y direction. FIG. 4 is a plan view of the magnetoresistance effect element 100 viewed in the z direction.

For example, the magnetoresistance effect element 100 includes a laminate 10, the spin-orbit torque wiring 20, the first via wiring 30, and the second via wiring 40.

The magnetoresistance effect element 100 is a magnetic element utilizing a spin-orbit torque (SOT) and may be referred to as a spin-orbit torque-type magnetoresistance effect element, a spin injection-type magnetoresistance effect element, or a spin current magnetoresistance effect element.

The magnetoresistance effect element 100 is an element which records and saves data. The magnetoresistance effect element 100 records data by a resistance value in the z direction of the laminate 10. The resistance value in the z direction of the laminate 10 varies when a writing current is applied along the spin-orbit torque wiring 20 and spins are injected into the laminate 10 from the spin-orbit torque wiring 20. The resistance value in the z direction of the laminate 10 can be read by applying a reading current in the z direction of the laminate 10.

The laminate 10 is connected to the spin-orbit torque wiring 20. For example, the laminate 10 is laminated on the spin-orbit torque wiring 20.

The laminate 10 is a columnar body. For example, the shape of the laminate 10 in a plan view in the z direction is a circular shape, an oval shape, or a quadrangular shape. For example, side surfaces of the laminate 10 are inclined with respect to the z direction.

For example, the laminate 10 includes a first ferromagnetic layer 1, a second ferromagnetic layer 2, a nonmagnetic layer 3, a base layer 4, a cap layer 5, and a mask layer 6. The resistance value of the laminate 10 varies in accordance with the difference in the relative angle of magnetization between the first ferromagnetic layer 1 and the second ferromagnetic layer 2 sandwiching the nonmagnetic layer 3 therebetween.

For example, the first ferromagnetic layer 1 faces the spin-orbit torque wiring 20. The first ferromagnetic layer 1 may come into direct contact with the spin-orbit torque wiring 20 or may come into indirect contact with it with the base layer 4 therebetween. For example, the first ferromagnetic layer 1 is laminated on the spin-orbit torque wiring 20.

Spins are injected into the first ferromagnetic layer 1 from the spin-orbit torque wiring 20. Magnetization of the first ferromagnetic layer 1 receives a spin-orbit torque (SOT) by injected spins so that the orientation direction thereof varies. The first ferromagnetic layer 1 is referred to as a magnetization free layer.

The first ferromagnetic layer 1 includes a ferromagnetic body. For example, the ferromagnetic body is a metal selected from the group consisting of Cr, Mn, Co, Fe, and Ni; an alloy including one or more kinds of these metals; an alloy including at least one or more kinds of elements of these metals, B, C, and N; or the like. For example, the ferromagnetic body is an alloy of Co—Fe, Co—Fe—B, Ni—Fe, or Co—Ho; a Sm—Fe alloy; a Fe—Pt alloy; a Co—Pt alloy; or a CoCrPt alloy.

The first ferromagnetic layer 1 may include a Heusler alloy. The Heusler alloy includes an intermetallic compound having a chemical composition of XYZ or X₂YZ. X represents a transition metal element or a noble metal element of the Co-group, the Fe-group, the Ni-group, or the Cu-group on the periodic table, Y represents a transition metal of the Mn-group, the V-group, the Cr-group, or the Ti-group or an element represented by X, and Z represents a typical element of Group III to Group V. For example, the Heusler alloy consists of Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The Heusler alloy has a high spin polarization.

The second ferromagnetic layer 2 faces the first ferromagnetic layer 1 with the nonmagnetic layer 3 sandwiched therebetween. The second ferromagnetic layer 2 includes a ferromagnetic body. The orientation direction of magnetization of the second ferromagnetic layer 2 is less likely to vary than that of magnetization of the first ferromagnetic layer 1 when a predetermined external force is applied. The second ferromagnetic layer 2 is referred to as a magnetization fixed layer or a magnetization reference layer. In the laminate 10 shown in FIG. 3, the magnetization fixed layer is located on a side away from the substrate Sub and is referred to as a top pin structure.

A material similar to that constituting the first ferromagnetic layer 1 is used as the material constituting the second ferromagnetic layer 2.

The second ferromagnetic layer 2 may have a synthetic antiferromagnetic structure (SAF structure). The synthetic antiferromagnetic structure is constituted of two magnetic layers sandwiching a nonmagnetic layer therebetween. The second ferromagnetic layer 2 may have two magnetic layers and a spacer layer sandwiched between these. Due to antiferromagnetic coupling between two ferromagnetic layers, the coercivity of the second ferromagnetic layer 2 increases. For example, the ferromagnetic layers are made of IrMn, PtMn, or the like. For example, the spacer layer includes at least one selected from the group consisting of Ru, Ir, and Rh.

The nonmagnetic layer 3 is sandwiched between the first ferromagnetic layer 1, and the second ferromagnetic layer 2. The nonmagnetic layer 3 includes a nonmagnetic body. When the nonmagnetic layer 3 is an insulator (when it is a tunnel barrier layer), for example, Al₂O₃, SiO₂, MgO, MgAl₂O₄, or the like can be used as a material thereof. In addition to these, it is also possible to use a material or the like in which a part of Al, Si, or Mg is replaced with Zn, Be, or the like. Among these, since MgO and MgAl₂O₄ are materials which can realize coherent tunneling, spins can be efficiently injected. When the nonmagnetic layer 3 is made of a metal, Cu, Au, Ag, or the like can be used as a material thereof. Moreover, when the nonmagnetic layer 3 is constituted of a semiconductor, Si, Ge, CuInSe₂, CuGaSe₂, Cu(In, Ga) Sez, or the like can be used as a material thereof.

For example, the base layer 4 is located between the first ferromagnetic layer 1 and the spin-orbit torque wiring 20. The base layer 4 may be omitted.

For example, the base layer 4 includes a buffer layer and a seed layer. The buffer layer is a layer mitigating lattice mismatch between different crystals. The seed layer increases the crystallinity of layers laminated on the seed layer. For example, the seed layer is formed on the buffer layer.

For example, the buffer layer is made of Ta (single material), TaN (tantalum nitride), CuN (copper nitride), TIN (titanium nitride), or NiAl (nickel aluminum). For example, the seed layer is made of Pt, Ru, Zr, a NiCr alloy, or NiFeCr.

The cap layer 5 is located on the second ferromagnetic layer 2. For example, the cap layer 5 increases magnetic anisotropy of the second ferromagnetic layer 2. For example, the cap layer 5 increases perpendicular magnetic anisotropy of the second ferromagnetic layer 2. For example, the cap layer 5 is made of magnesium oxide, W, Ta, Mo, or the like. For example, the film thickness of the cap layer 5 is 0.5 nm to 5.0 nm.

The mask layer 6 is located on the cap layer 5. The mask layer 6 is a part of a hard mask used when processing the laminate 10 at the time of manufacturing. The mask layer 6 also functions as an electrode. For example, the mask layer 6 includes Al, Cu, Ta, Ti, Zr, NiCr, nitrides (for example, TiN, TaN, or SiN), or oxides (for example, SiO₂).

The laminate 10 may have a layer other than the first ferromagnetic layer 1, the second ferromagnetic layer 2, the nonmagnetic layer 3, the base layer 4, the cap layer 5, and the mask layer 6.

For example, the spin-orbit torque wiring 20 has a length which is longer in the x direction than in the y direction when viewed in the z direction and extends in the x direction. A writing current flows in the x direction along the spin-orbit torque wiring 20 between the first via wiring 30 and the second via wiring 40.

The spin-orbit torque wiring 20 generates a spin current due to a spin Hall effect occurring when a current flows and injects spins into the first ferromagnetic layer 1. For example, the spin-orbit torque wiring 20 applies enough spin-orbit torque (SOT) to the magnetization of the first ferromagnetic layer 1 to reverse the magnetization of the first ferromagnetic layer 1.

The spin Hall effect is a phenomenon in which a spin current is induced in a direction orthogonal to the flowing direction of a current based on a spin-orbit interaction when a current flows. The spin Hall effect is in common with a normal Hall effect in that transferring (moving) charge (electrons) can bend the transferring (moving) direction. The normal Hall effect causes the transferring direction of transferring charged particles in a magnetic field to bend by means of a Lorentz force. In contrast, the spin Hall effect causes the moving direction of spins to bend simply by means of moving electrons (flowing currents) even if there is no magnetic field.

For example, if a current flows in the spin-orbit torque wiring 20, first spins polarized in one direction and second spins polarized in a direction opposite to that of the first spins individually bend due to the spin Hall effect in a direction orthogonal to the flowing direction of the current. For example, the first spins polarized in the negative y direction bend in the positive z direction from the x direction that is the traveling direction thereof, and the second spins polarized in the positive y direction bend in the negative z direction from the x direction that is the traveling direction thereof.

In the nonmagnetic body (a material that is not a ferromagnetic body), the number of electrons in the first spins and the number of electrons in the second spins generated due to the spin Hall effect are the same. That is, the number of electrons in the first spins toward the positive z direction and the number of electrons in the second spins toward the negative z direction are the same. The first spins and the second spins flow in directions in which an uneven distribution of the spins is eliminated. Since flows of charge are offset each other in movement of the first spins and the second spins in the z direction, the current amount becomes zero. A spin current accompanying no current is particularly referred to as a pure spin current.

When a flow of electrons in the first spins is expressed as J_{↑}, a flow of electrons in the second spins is expressed as J_{↓}, and a spin current is expressed as J_{S}, these are defined as J_{S}=J_{↑}−J_{↓}. The spin current J_{S} is generated in the z direction. The first spins are injected into the first ferromagnetic layer 1 from the spin-orbit torque wiring 20.

The spin-orbit torque wiring 20 includes any of a metal, an alloy, an intermetallic compound, a metal boride, a metal carbide, a metal silicide, a metal phosphide, and a metal nitride having a function of generating a spin current due to the spin Hall effect occurring when a writing current flows. For example, the spin-orbit torque wiring 20 includes any one selected from the group consisting of a heavy metal whose atomic number is 39 or larger, a metal oxide, a metal nitride, a metal oxynitride, and a topological insulator.

For example, the spin-orbit torque wiring 20 includes a nonmagnetic heavy metal as a main component. A heavy metal denotes a metal having a specific gravity equal to or greater than that of yttrium (Y). For example, a nonmagnetic heavy metal is a nonmagnetic metal having d electrons or f electrons in an outermost shell and having a large atomic number (the atomic number 39 or larger). For example, the spin-orbit torque wiring 20 is made of Hf, Ta, or W. In a nonmagnetic heavy metal, a spin-orbit interaction stronger than those in other metals occurs. A spin Hall effect occurs due to a spin-orbit interaction, and spins are likely to be unevenly distributed inside the spin-orbit torque wiring 20 so that the spin current J_{S} is likely to be generated.

The spin-orbit torque wiring 20 may further include a magnetic metal. The magnetic metal is a ferromagnetic metal or an antiferromagnetic metal. A minute amount of the magnetic metal included in the nonmagnetic body becomes a scattering factor of spins. For example, a minute amount indicates 3% or smaller than the total mole ratio of the elements constituting the spin-orbit torque wiring 20. When spins scatter due to the magnetic metal, the spin-orbit interaction is strengthened, and generation efficiency of a spin current with respect to a current is enhanced.

The spin-orbit torque wiring 20 may include a topological insulator. The topological insulator is a substance in which the interior of the substance is an insulator or a high-resistance body and a spin-polarized metal state has occurred on its surface. An internal magnetic field is generated in the topological insulator due to the spin-orbit interaction. In the topological insulator, a new topological phase develops due to an effect of the spin-orbit interaction even if there is no external magnetic field. The topological insulator can generate a pure spin current with high efficiency due to the strong spin-orbit interaction and breaking of reversal symmetry at edges.

For example, the topological insulator is made of SnTe, Bi_{1.5}Sb_{0.5}Te_{1.7}Se_{1.3}, TIBiSe₂, Bi₂Te₃, Bi₁₋ₓSbₓ, (Bi₁₋ₓSbₓ)₂Te₃ or the like. The topological insulator can generate a spin current with high efficiency.

The spin-orbit torque wiring 20 has a first region 21, a second region 22, and a third region 23. The spin-orbit torque wiring 20 is divided into three regions, that is, the first region 21, the second region 22, and the third region 23 in the x direction. The first region 21, the second region 22, and the third region 23 include the same material.

The first region 21 is a region which does not overlap the first ferromagnetic layer 1 in the z direction and comes into contact with the first via wiring 30. The second region 22 is a region which does not overlap the first ferromagnetic layer 1 in the z direction and comes into contact with the second via wiring 40. The third region 23 is a region which overlaps the first ferromagnetic layer 1 in the z direction. For example, a boundary between the first region 21 and the third region 23 is a yz plane passing through a first end of the first ferromagnetic layer 1 in the x direction. For example, a boundary between the second region 22 and the third region 23 is a yz plane passing through a second end of the first ferromagnetic layer 1 in the x direction.

For example, the first region 21 has a higher crystallinity than the third region 23. For example, the second region 22 has a higher crystallinity than the third region 23.

For example, the crystallinity of each region can be evaluated using X-ray diffraction, a transmission-type electron microscopy image (for example, a high angle scattering annular dark field scanning transmission electron microscopy image: HAADF-STEM image), a transmission-type electron beam using an electron beam diffraction image, or a reflection high energy electron diffraction method.

For example, a difference in crystallinity between the regions can be obtained by the following procedure. Hereinafter, a case of comparing the crystallinities of the first region 21 and the third region 23 will be described as an example.

First, each of the first region 21 and the third region 23 is divided into five regions in the x direction. Further, X-ray diffraction is performed with respect to each part of the five divided regions, and the presence or absence of an X-ray diffraction peak is confirmed. An X-ray diffraction peak is a peak generated when the elements constituting the spin-orbit torque wiring 20 are crystallized. When an X-ray diffraction peak is confirmed, it can be estimated that the part is crystallized.

For example, when the number of parts which can be estimated to be crystallized at five measurement points in the first region 21 is larger than the number of parts which can be estimated to be crystallized at five measurement points in the third region 23, it can be said that the first region 21 has a higher crystallinity than the third region 23.

Here, in results of X-ray diffraction of the first region 21 and the third region 23, when an X-ray diffraction peak is confirmed in all parts of both regions, average values of peak intensities of X-ray diffraction are compared. When the average value of the peak intensities of the third region 23 is larger than the average value of the peak intensities of the first region 21, it can be said that the first region 21 has a higher crystallinity than the third region 23. When the average values of the peak intensities of the first region 21 and the third region 23 are the same, average values of half-value widths of the peaks are compared. When the average value of the half-value width of the third region 23 is smaller than the average value of the half-value width of the first region 21, it can be said that the first region 21 has a higher crystallinity than the third region 23. In addition, a difference in crystallinity between the regions may be obtained by the following procedure.

If an HAADF-STEM image is captured using a TEM, a state in which atoms are periodically arrayed can be confirmed. Each of the captured images of the first region 21 and the third region 23 is divided into five regions in the x direction, and each image is evaluated.

For example, when the number of parts where a periodic atomic array can be confirmed at five measurement points in the first region 21 is larger than the number of parts where a periodic atomic array can be confirmed at five measurement points in the third region 23, it can be said that the first region 21 has a higher crystallinity than the third region 23.

In addition, when a periodic atomic array can be confirmed in all the measurement images of the first region 21 and the third region, a period (lattice constant) of the atomic array is obtained at each of the five measurement points in each of the first region 21 and the third region 23. Regarding crystal structures of molecules constituting the spin-orbit torque wiring 20, an α phase and a β phase are conceivable. The α phase has a simpler structure with fewer atoms included in the unit cell of the crystal than the β phase, and has a high crystallinity. The α phase has a smaller lattice constant than the β phase. The α phase has more crystal axes with rotational symmetry or a larger number of symmetries than the β phase. Each of the lattice constants of the α phase and the β phase of the molecules constituting the spin-orbit torque wiring 20 is known.

Regarding the lattice constants measured at the measurement points, when a deviation with respect to the lattice constant of the α phase is within 10%, the measurement point can be estimated to be the α phase. Regarding the lattice constants measured at the measurement points, when a deviation with respect to the lattice constant of the β phase is within 10%, the measurement point can be estimated to be the β phase. For this reason, when the number of parts of the five measurement points in the first region 21 estimated to be the α phase is larger than the number of parts of the five measurement points in the third region 23 estimated to be the α phase, it can be said that the first region 21 has a higher crystallinity than the third region 23.

In addition, here, a method for judging a difference in crystallinity between the first region 21 and the third region by measuring a lattice constant has been described, but it may be judged using an electron beam diffraction image using a transmission-type electron beam.

The α phase and the β phase have different crystal structures. For this reason, positions of generated spots derived from the crystal structure in the electron beam diffraction images differ. It may be estimated whether each of the measurement points is the α phase or the β phase from the position of the spot. When the number of parts of the five measurement points in the first region 21 estimated to be the α phase is larger than the number of parts of the five measurement points in the third region 23 estimated to be the α phase, it can be said that the first region 21 has a higher crystallinity than the third region 23.

Thus far, a case of comparing the crystallinities of the first region 21 and the third region 23 has been described as an example, a similar procedure can also be performed for a case of comparing the crystallinities between two other regions. In addition, the number of measurement points does not necessarily have to be five, and the measurement points may be increased or decreased. When the difference in crystallinity between the regions to be compared is significant, since there may be a significant difference in measurement results, the number of measurement points may be reduced. When the difference in crystallinity between the regions to be compared is small, evaluation of the difference in crystallinity is facilitated by increasing the number of measurement points.

For example, the first region 21 and the second region 22 are the α phase, and for example, the third region 23 is the β phase or amorphous. For example, tungsten and tantalum are materials which allow both the α phase and the β phase to be selected. For example, the first region 21 and the second region 22 are made of α-tungsten, and the third region 23 is made of β-tungsten.

In addition, the first region 21 may have a first high crystalline region and a first low crystalline region. The first high crystalline region has a higher crystallinity than the first low crystalline region. For example, when the first high crystalline region is the α phase, the first low crystalline region is the β phase or amorphous. For example, when the first high crystalline region is the β phase, the first low crystalline region is amorphous.

In the first region 21, for example, it is preferable that the proportion of the first high crystalline region be 50% or higher. For example, when the first region 21 has the α phase and the β phase, it is preferable that the proportion of the α phase be 50% or higher. The α phase and the β phase are judged in accordance with the foregoing procedure.

In addition, the first region 21 may have a crystal transition region between the first high crystalline region and the first low crystalline region. For example, the crystal transition region is a region of several nm or larger in the x direction.

In addition, the third region 23 may have a second high crystalline region and a second low crystalline region. The second high crystalline region has a higher crystallinity than the second low crystalline region. For example, when the second high crystalline region is the α phase, the second low crystalline region is the β phase or amorphous. For example, when the second high crystalline region is the β phase, the second low crystalline region is amorphous.

In the third region 23, for example, it is preferable that the proportion of the second low crystalline region be 50% or higher. For example, when the third region 23 has the β phase and an amorphous part, it is preferable that the proportion of the amorphous part be 50% or higher.

In addition, the third region 23 may have a crystal transition region between the second high crystalline region and the second low crystalline region. For example, the crystal transition region is a region of several nm or larger in the x direction.

In addition, the second region 22 may have a third high crystalline region and a third low crystalline region. The third high crystalline region has a higher crystallinity than the third low crystalline region. For example, when the third high crystalline region is the α phase, the third low crystalline region is the β phase or amorphous. For example, when the third high crystalline region is the β phase, the third low crystalline region is amorphous.

In the second region 22, for example, it is preferable that the proportion of the third high crystalline region be 50% or higher. The second region 22 may have a crystal transition region between the third high crystalline region and the third low crystalline region. For example, the crystal transition region is a region of several nm or larger in the x direction.

For example, the electrical resistivity of the first region 21 is lower than the electrical resistivity of the third region 23. In addition, for example, the electrical resistivity of the second region 22 is lower than the electrical resistivity of the third region 23. When the electrical resistance value between the first via wiring 30 and the second via wiring 40 is measured and the following relational expression is established, it can be said that the electrical resistivity of the first region 21 or the second region 22 is lower than the electrical resistivity of the third region 23. Here, R represents a measured electrical resistance value, L₁ represents the shortest distance from the boundary between the first region 21 and the third region 23 to the first via wiring 30, L₂ represents the shortest distance from the boundary between the second region 21 and the third region 23 to the second via wiring 40, L₃ represents the length of the third region in the x direction, t₁, t₂, and t₃ respectively represent the smallest thicknesses of the first region 21, the second region 22, and the third region 23, and w₁, w₂, and w₃ respectively represents the smallest widths of the first region 21, the second region 22, and the third region 23.

$$R > \frac{50}{{w}_{1} {w}_{2} {w}_{3}} ( \frac{{L}_{1}}{{t}_{1}} {w}_{2} {w}_{3} + \frac{{L}_{2}}{{t}_{2}} {w}_{3} {w}_{1} + \frac{{L}_{3}}{{t}_{3}} {w}_{1} {w}_{2} ) \qquad [ Math . 1 ]$$

The spin-orbit torque wiring 20 is not limited to a single layer and may be a laminate of a plurality of layers. For example, the spin-orbit torque wiring 20 may have a plurality of heavy metal layers and insertion layers sandwiched therebetween.

For example, the electrical resistivity of the spin-orbit torque wiring 20 is 10 μΩ·cm or higher. In addition, for example, the electrical resistivity of the spin-orbit torque wiring 20 is 5 mΩ·cm or lower. If the electrical resistivity of the spin-orbit torque wiring 20 is high, a high voltage can be applied to the spin-orbit torque wiring 20. If the potential of the spin-orbit torque wiring 20 increases, spins can be efficiently supplied from the spin-orbit torque wiring 20 to the first ferromagnetic layer 1. In addition, since the spin-orbit torque wiring 20 has conductivity equal to or higher than a certain level, a path for a current flowing along the spin-orbit torque wiring 20 can be secured, and thus a spin current involving the spin Hall effect can be efficiently generated.

For example, the thickness of the spin-orbit torque wiring 20 is 3 nm or larger. For example, the thickness of the spin-orbit torque wiring 20 is 20 nm or smaller.

The first via wiring 30 is connected to a first end of the spin-orbit torque wiring 20. The first via wiring 30 is a columnar body. The first via wiring 30 may be a laminate of a plurality of columnar bodies. For example, the columnar body is a round column, an elliptic cylinder, or a prismatic column.

For example, the first via wiring 30 has a contact region 31. The contact region 31 is a region of the first via wiring 30 which comes into contact with the spin-orbit torque wiring 20. For example, when the first via wiring 30 is constituted of a plurality of columnar bodies, the columnar body of the first via wiring 30 closest to the spin-orbit torque wiring 20 is the contact region 31. For example, the crystallinity of the contact region 31 is higher than the crystallinity of the third region 23. For example, the crystallinity of the contact region 31 is higher than the crystallinity of the first region 21.

The first via wiring 30 includes a conductive material. It is preferable that a main component of the elements constituting the contact region 31 be the same as a main component of the elements constituting the spin-orbit torque wiring 20. Details will be described below. The first region 21 is affected by the crystal structure of the contact region 31 and crystallization thereof is prompted. If the elements constituting the contact region 31 and the spin-orbit torque wiring 20 are the same, crystallization of the first region 21 is further prompted. For example, the contact region 31 is made of tantalum, platinum, molybdenum, or tungsten.

There is no particular limitation on the material constituting parts of the first via wiring 30 other than the contact region 31, as long as it is conductive.

The second via wiring 40 comes into contact with the spin-orbit torque wiring 20 at a position sandwiching the first ferromagnetic layer 1 with the first via wiring 30 in the z direction. The second via wiring 40 may be connected to the same surface as the first via wiring 30 of the spin-orbit torque wiring 20 or may be connected to a different surface.

For example, the second via wiring 40 may have a contact region 41. The contact region 41 is a region of the second via wiring 40 which comes into contact with the spin-orbit torque wiring 20. For example, when the second via wiring 40 is constituted of a plurality of columnar bodies, the columnar body of the second via wiring 40 closest to the spin-orbit torque wiring 20 is the contact region 41. For example, the crystallinity of the contact region 41 is higher than the crystallinity of the third region 23. For example, the crystallinity of the contact region 41 is higher than the crystallinity of the second region 22.

The second via wiring 40 is made of a material similar to that of the first via wiring 30. It is preferable that a main component of the elements constituting the contact region 41 be the same as a main component of the elements constituting the spin-orbit torque wiring 20.

Next, a method for manufacturing the magnetoresistance effect element 100 will be described. The magnetoresistance effect element 100 is formed through a step of laminating layers and a processing step of processing a portion of each layer into a predetermined shape. Each layer can be laminated using a sputtering method, a chemical vapor deposition (CVD) method, an electron beam evaporation method (EB evaporation method), an atom laser deposition method, or the like. Each layer can be processed using photolithography or the like.

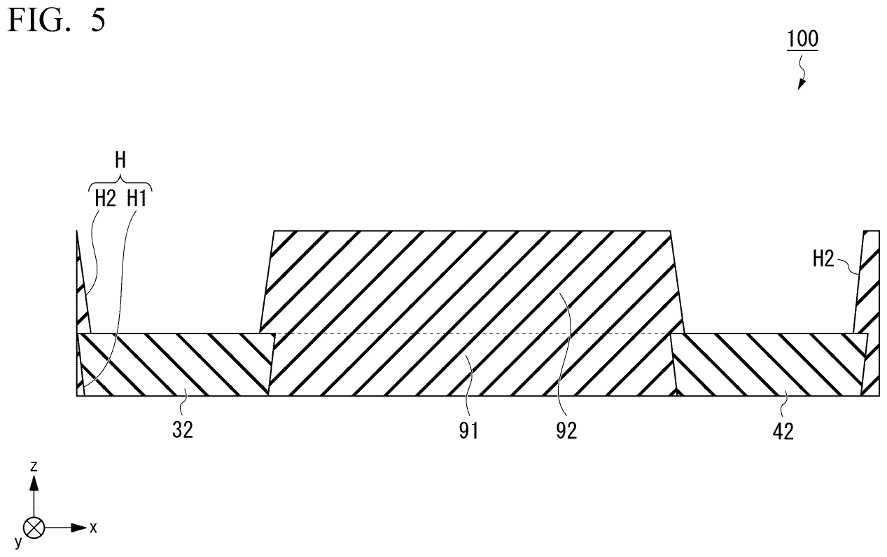

First, as shown in FIG. 5, an insulating layer 91 is subjected to film formation, an opening H1 is formed at a predetermined position, and the opening H1 is filled with sacrificial layers 32 and 42. Next, an insulating layer 92 is subjected to film formation on the sacrificial layers 32 and 42 and the insulating layer 91. Next, openings H2 are formed at positions overlapping the sacrificial layers 32 and 42 of the insulating layer 92. The opening H1 and the openings H2 become a continuous opening H by removing the sacrificial layers 32 and 42.

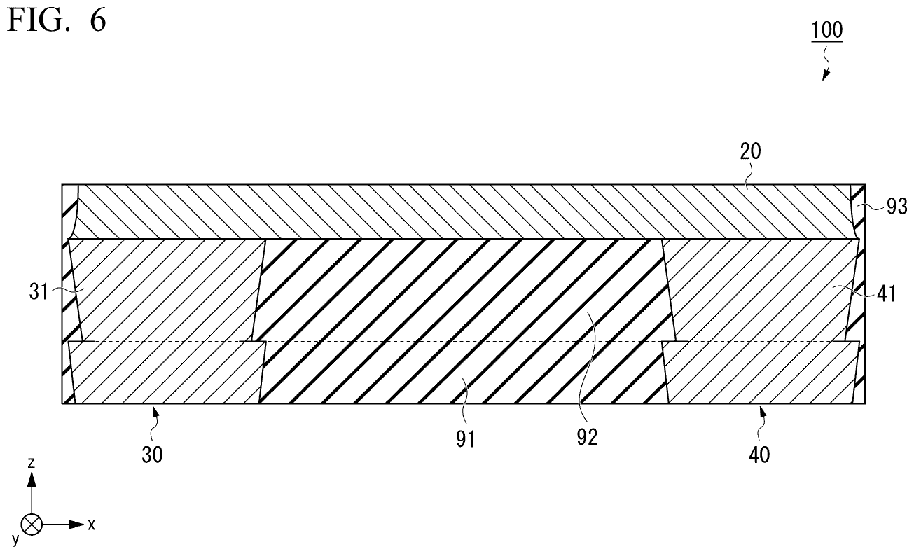

Next, as shown in FIG. 6, the opening H is filled with a conductor. The opening H filled with a conductor serves as the first via wiring 30 and the second via wiring 40. It is preferable that the contact regions 31 and 41 be made of the same material as the spin-orbit torque wiring 20.

Next, a layer that will serve as the spin-orbit torque wiring 20 is subjected to film formation on the first via wiring 30, the second via wiring 40, and the insulating layer 92. The spin-orbit torque wiring 20 is obtained by processing the layer that will serve as the spin-orbit torque wiring 20 into a predetermined shape. The spin-orbit torque wiring 20 is connected to the first via wiring 30 having the contact region 31 with a higher crystallinity than the spin-orbit torque wiring 20 such that the spin-orbit torque wiring 20 comes into contact with the contact region 31.

Next, an area around the spin-orbit torque wiring 20 is covered by an insulating layer 93. Further, a part of the covered insulating layer 93 is subjected to chemical mechanical polishing (CMP). An upper surface of the spin-orbit torque wiring 20 is exposed and flattened by performing CMP.

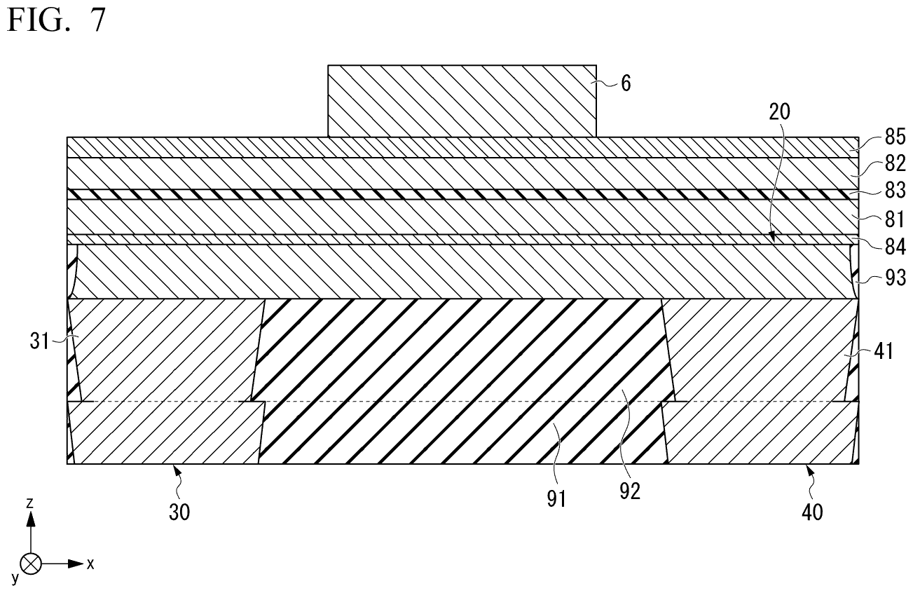

Next, as shown in FIG. 7, a base layer 84, a ferromagnetic layer 81, a nonmagnetic layer 83, a ferromagnetic layer 82, and a cap layer 85 are sequentially laminated on the spin-orbit torque wiring 20. Further, the mask layer 6 is formed on a portion of the cap layer 85.

Next, the laminate 10 is obtained by processing each of the laminated layers into a predetermined shape with the mask layer 6 therebetween. The base layer 84 becomes the base layer 4, the ferromagnetic layer 81 becomes the first ferromagnetic layer 1, the nonmagnetic layer 83 becomes the nonmagnetic layer 3, the ferromagnetic layer 82 becomes the second ferromagnetic layer 2, and the cap layer 85 becomes the cap layer. Further, an area around the laminate 10 is covered by an insulating layer.

Next, the spin-orbit torque wiring 20 and the first via wiring 30 are heated, at least. For example, it is preferable that the heating temperature be 200° C. or higher. Atoms constituting the first region 21 are arrayed again due to an influence of the crystal structure of the contact region 31. Since atoms of the first region 21 are arrayed again, crystallization is prompted. Similarly, atoms constituting the second region 22 are arrayed again due to an influence of the crystal structure of the contact region 41. Since atoms of the second region 22 are arrayed again, crystallization is prompted.

Through such a procedure, it is possible to obtain the magnetoresistance effect element 100 having the spin-orbit torque wiring 20 in which the crystallinities of the first region 21 and the third region 23 differ. In addition, after the first via wiring 30 and the second via wiring 40 are formed, the first via wiring 30, the second via wiring 40, and the insulating layer 92 may be subjected to CMP. In this case, the spin-orbit torque wiring 20 and the laminate 10 are formed by continuously performing film formation of the layer that will serve as the spin-orbit torque wiring 20 and the layer that will serve as the laminate 10 and processing them into predetermined shapes over a plurality of times. Next, the magnetoresistance effect element 100 is obtained by at least heating the spin-orbit torque wiring 20 and the first via wiring 30

The magnetoresistance effect element 100 according to the first embodiment has high energy efficiency. The reason for this will be described.

In order to make magnetization reversal of magnetization of the first ferromagnetic layer 1 stable, it is preferable that the electrical resistivity of the spin-orbit torque wiring 20 be high. If the electrical resistivity of the spin-orbit torque wiring 20 is high, generation efficiency of a spin current is enhanced. On the other hand, if the electrical resistivity of the spin-orbit torque wiring 20 is high, the spin-orbit torque wiring 20 generates heat when in use. If the spin-orbit torque wiring 20 generates heat, the spin-orbit torque wiring 20 may break. That is, from the viewpoint of facilitating magnetization reversal, it is required to increase the electrical resistivity of the spin-orbit torque wiring 20, whereas from the viewpoint of reducing heat generation and the like, it is required to decrease the electrical resistivity of the spin-orbit torque wiring 20.

The spin-orbit torque wiring 20 according to the present embodiment has the first region 21 and the second region 22 having a high crystallinity, and the third region 23 having a low crystallinity. The first region 21 and the second region 22 have a lower electrical resistivity than the third region 23.

A spin current is injected into the first ferromagnetic layer 1 from the third region 23 and reverses magnetization of the first ferromagnetic layer 1. For this reason, an influence of the third region 23 on magnetization reversal of the first ferromagnetic layer 1 is greater than those of the first region 21 and the second region 22. In other words, an influence of spins generated in the first region 21 and the second region 22 on magnetization reversal of the first ferromagnetic layer 1 is smaller than an influence of spins generated in the third region 23 on magnetization reversal of the first ferromagnetic layer 1.

Namely, the first region 21 and the second region 22 are required to have a function of reducing heat generation and the like rather than a function of facilitating magnetization reversal. In contrast, the third region 23 is required to have a function of facilitating magnetization reversal rather than a function of reducing heat generation and the like.

In this manner, the magnetoresistance effect element 100 according to the present embodiment can realize efficient and stable magnetization reversal while avoiding unnecessary heat generation and the like.

### Second Embodiment

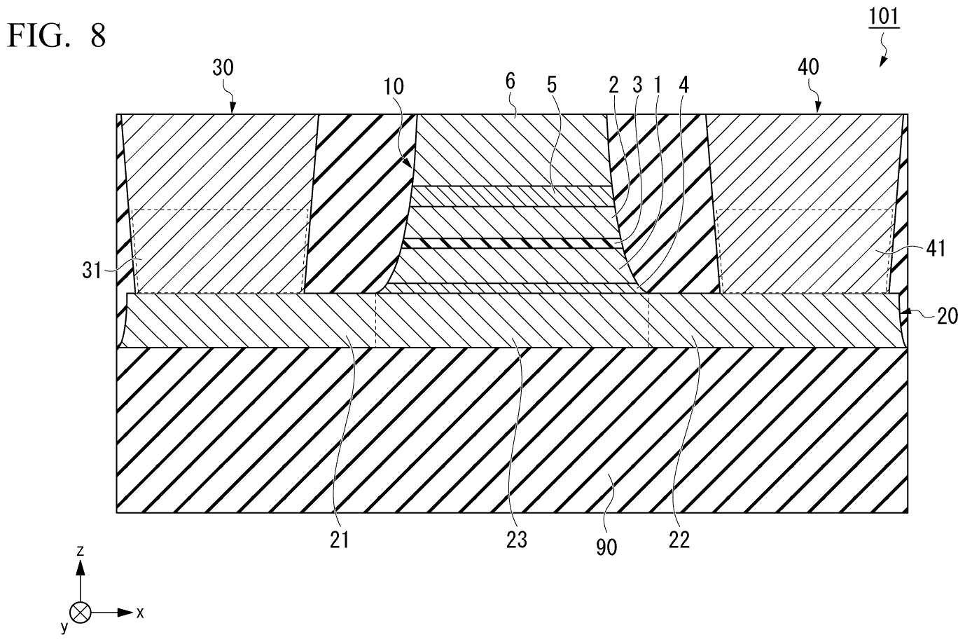

FIG. 8 is a cross-sectional view of a magnetoresistance effect element 101 according to a second embodiment. The magnetoresistance effect element 101 according to the second embodiment differs from the magnetoresistance effect element 100 according to the first embodiment in connection surfaces of the first via wiring 30 and the second via wiring 40 with respect to the spin-orbit torque wiring 20. In the magnetoresistance effect element 101 according to the second embodiment, the same reference signs are applied to constituents similar to those of the magnetoresistance effect element 100, and description thereof will be omitted.

The magnetoresistance effect element 101 according to the second embodiment differs from the magnetoresistance effect element 100 according to the first embodiment in production order in which the first via wiring 30 and the second via wiring 40 are produced after the spin-orbit torque wiring 20 and the laminate 10 are produced. The magnetoresistance effect element 101 is produced through the following procedure.

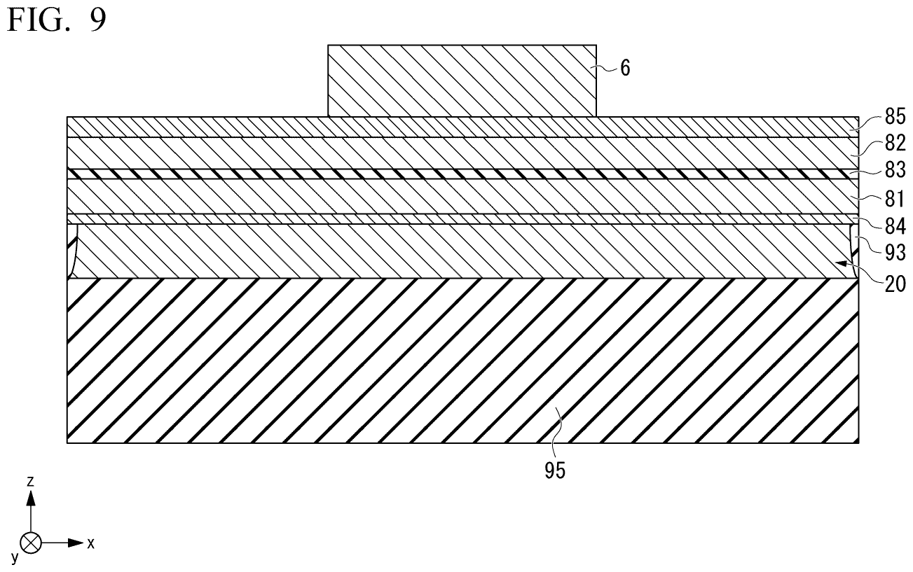

First, as shown in FIG. 9, a layer that will serve as the spin-orbit torque wiring 20 is subjected to film formation on an insulating layer 95. The spin-orbit torque wiring 20 is obtained by processing the layer that will serve as the spin-orbit torque wiring 20 into a predetermined shape. An area around the spin-orbit torque wiring 20 is covered by the insulating layer 93. Next, the upper surface of the spin-orbit torque wiring 20 is exposed through CMP, and the base layer 84, the ferromagnetic layer 81, the nonmagnetic layer 83, the ferromagnetic layer 82, and the cap layer 85 are sequentially laminated. Further, the mask layer 6 is formed on a portion of the cap layer 85.

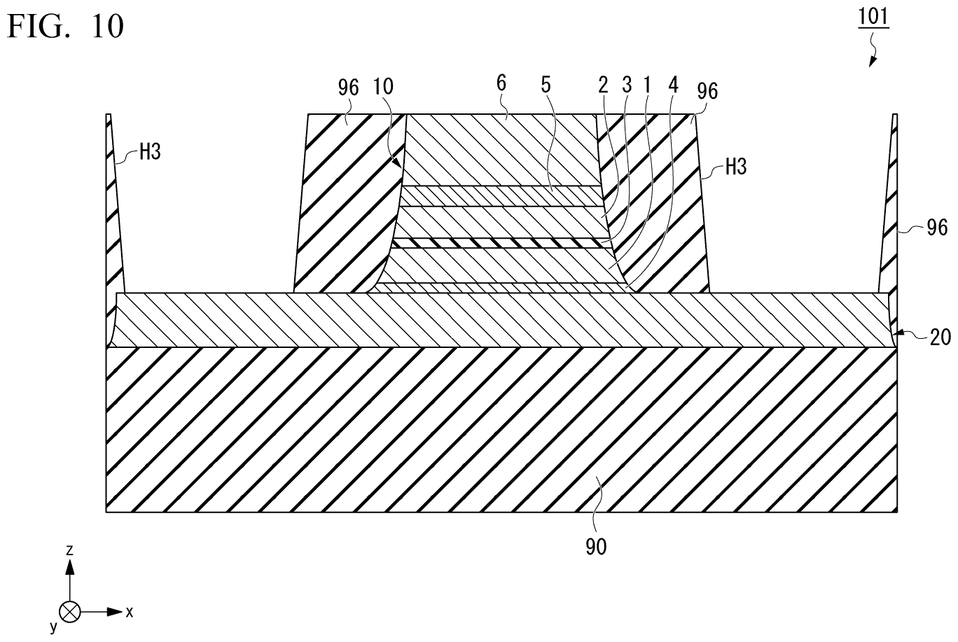

Next, as shown in FIG. 10, the laminate 10 is obtained by processing each of the laminated layers into a predetermined shape with the mask layer 6 therebetween. Further, an area around the laminate 10 is covered by an insulating layer 96. Further, two openings H3 are formed at predetermined positions in the insulating layer 96.

Next, the first via wiring 30 and the second via wiring 40 are formed by filling the openings H3 with a conductor. It is preferable that the contact regions 31 and 41 be made of the same material as the spin-orbit torque wiring 20. The spin-orbit torque wiring 20 is connected to the first via wiring 30 having the contact region 31 with a higher crystallinity than the spin-orbit torque wiring 20 such that the spin-orbit torque wiring 20 comes into contact with the contact region 31.

Next, the spin-orbit torque wiring 20 and the first via wiring 30 are heated, at least. For example, it is preferable that the heating temperature be 200° C. or higher. Atoms constituting the first region 21 are arrayed again due to an influence of the crystal structure of the contact region 31. Since atoms of the first region 21 are arrayed again, crystallization is prompted. Similarly, atoms constituting the second region 22 are arrayed again due to an influence of the crystal structure of the contact region 41. Since atoms of the second region 22 are arrayed again, crystallization is prompted.

Through such a procedure, it is possible to obtain the magnetoresistance effect element 101 having the spin-orbit torque wiring 20 in which the crystallinities of the first region 21 and the third region 23 differ. Here, an example in which a layer that will serve as the spin-orbit torque wiring, and a laminate that is constituted of the base layer 84, the ferromagnetic layer 81, the nonmagnetic layer 83, the ferromagnetic layer 82, and the cap layer 85 are separately subjected to film formation and processing has been described. However, these may be processed over a plurality of times after performing film formation at the same time.

The magnetoresistance effect element 101 according to the second embodiment exhibits effects similar to those of the magnetoresistance effect element 100 according to the first embodiment.

Thus far, preferable aspects of a magnetoresistance effect element have been described with the first embodiment and the second embodiment as examples, but the present invention is not limited to these embodiments.

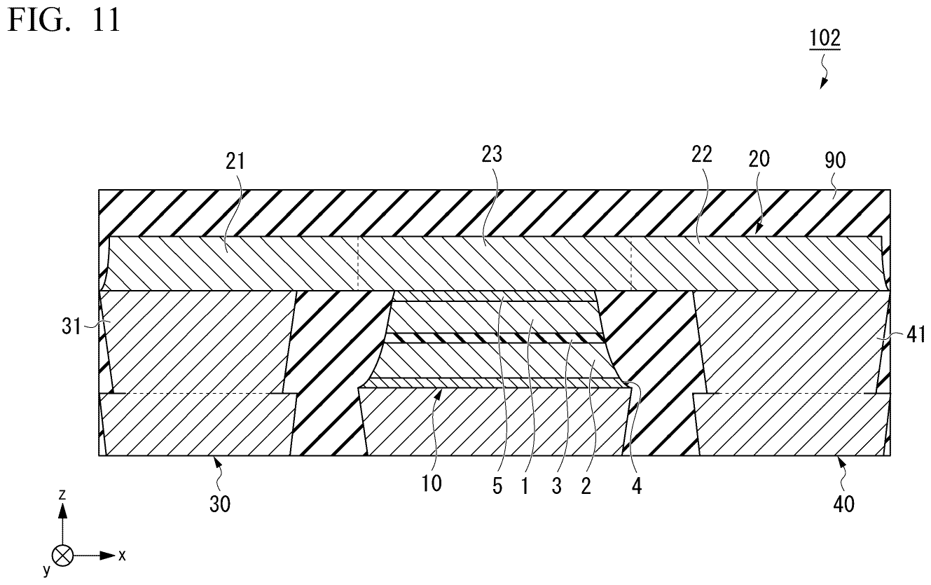

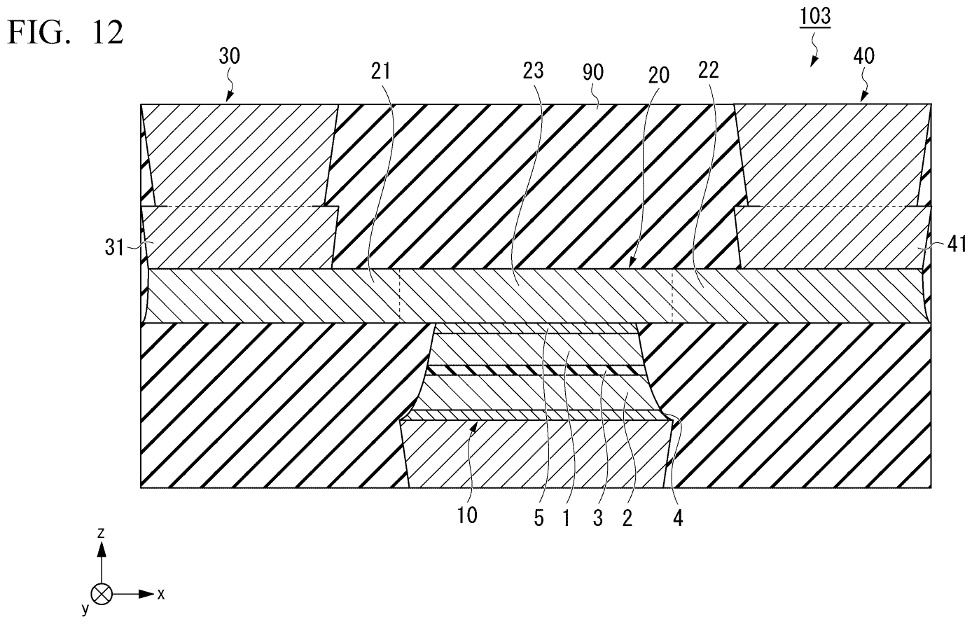

For example, FIG. 11 is a cross-sectional view of a magnetoresistance effect element 102 according to a first modification example. FIG. 12 is a cross-sectional view of a magnetoresistance effect element 103 according to a second modification example. In the first modification example and the second modification example, the same reference signs are applied to constituents similar to those of the first embodiment and the second embodiment, and description thereof will be omitted.

The magnetoresistance effect element 102 according to the first modification example differs from the magnetoresistance effect element 100 according to the first embodiment in positional relationship of the laminate 10 with respect to the spin-orbit torque wiring 20. The magnetoresistance effect element 103 according to the second modification example differs from the magnetoresistance effect element 101 according to the second embodiment in positional relationship of the laminate 10 with respect to the spin-orbit torque wiring 20. The magnetoresistance effect elements 102 and 103 are referred to as a bottom pin structure, in which the second ferromagnetic layer 2 serving as the magnetization fixed layer is close to the substrate Sub.

Each of the magnetoresistance effect elements 102 and 103 according to the first modification example and the second modification example exhibits effects similar to those of the magnetoresistance effect element 100 according to the first embodiment.

### Third Embodiment

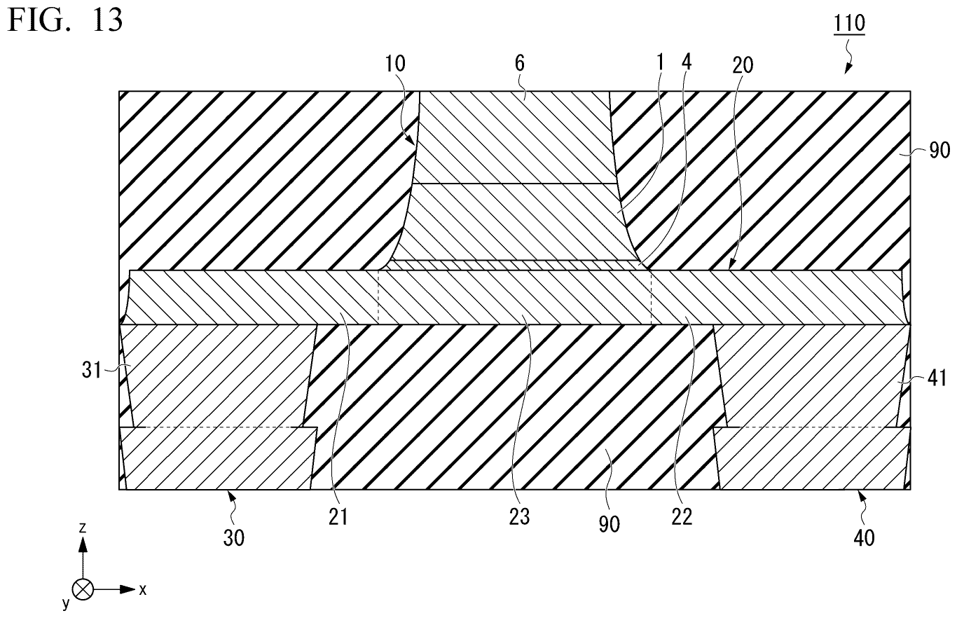

FIG. 13 is a cross-sectional view of a magnetization rotation element 110 according to a third embodiment. In FIG. 1, the magnetization rotation element 110 can replace the magnetoresistance effect element 100 according to the first embodiment. The magnetization rotation element 110 differs from the magnetoresistance effect element 100 in that the second ferromagnetic layer 2 and the nonmagnetic layer 3 are not provided.

For example, in the magnetization rotation element 110, light is caused to incident on the first ferromagnetic layer 1, and the light reflected by the first ferromagnetic layer 1 is evaluated. If the orientation direction of magnetization varies due to the magnetic Kerr effect, the deflection state of the reflected light varies. For example, the magnetization rotation element 110 can be used as an optical element, such as a video image display device, for example, utilizing a difference in deflection state of light.

Furthermore, the magnetization rotation element 110 can also be utilized alone as an anisotropy magnetic sensor, an optical element utilizing the magnetic Faraday effect, or the like.

The magnetization rotation element 110 according to the sixth embodiment is obtained by simply removing the nonmagnetic layer 3 and the second ferromagnetic layer 2 from the magnetoresistance effect element 100, and effects similar to those of the magnetoresistance effect element 100 according to the first embodiment can be achieved.

Thus far, preferable aspects of the present invention have been described as examples using several exemplary embodiments, but the present invention is not limited to these embodiments. For example, characteristic constituents in each of the embodiments may be applied to other embodiments and modification examples.

### REFERENCE SIGNS LIST

1 First ferromagnetic layer
2 Second ferromagnetic layer
3, 83 Nonmagnetic layer
4, 84 Base layer
5, 85 Cap layer
6 Mask layer
10 Laminate
20 Spin-orbit torque wiring
21 First region
22 Second region
23 Third region
30 First via wiring
31, 41 Contact region
32, 42 Sacrificial layer
40 Second via wiring
81, 82 Ferromagnetic layer
90, 91, 92, 93, 95, 96 Insulating layer
100, 101, 102, 103 Magnetoresistance effect element
110 Magnetization rotation element
200 Magnetic memory
Sub Substrate

1. A magnetization rotation element comprising:
a spin-orbit torque wiring;
a first ferromagnetic layer;
a first via wiring; and
a second via wiring,
wherein the first ferromagnetic layer faces at least a part of the spin-orbit torque wiring and is located between the first via wiring and the second via wiring in a lamination direction,
the spin-orbit torque wiring has a first region, a second region, and a third region,
the first region does not overlap the first ferromagnetic layer in the lamination direction and comes into contact with the first via wiring,
the second region does not overlap the first ferromagnetic layer in the lamination direction and comes into contact with the second via wiring,
the third region overlaps the first ferromagnetic layer in the lamination direction, and
the first region has a higher crystallinity than the third region.

2. The magnetization rotation element according to claim 1,
wherein the first via wiring has a contact region which comes into contact with the spin-orbit torque wiring, and
the contact region has a higher crystallinity than the third region.

3. The magnetization rotation element according to claim 2,
wherein a main component of elements constituting the contact region is the same as a main component of elements constituting the spin-orbit torque wiring.

4. The magnetization rotation element according to claim 1,
wherein the first region has a first high crystalline region and a first low crystalline region, and
in the first region, a proportion of the first high crystalline region is 50% or higher.

5. The magnetization rotation element according to claim 1,
wherein the third region has a second high crystalline region and a second low crystalline region, and
in the third region, a proportion of the second low crystalline region is 50% or higher.

6. A magnetoresistance effect element comprising at least:
the magnetization rotation element according to claim 1;
a nonmagnetic layer; and
a second ferromagnetic layer,
wherein the first ferromagnetic layer and the second ferromagnetic layer of the magnetization rotation element sandwich the nonmagnetic layer therebetween.

7. A magnetic memory comprising:
the magnetoresistance effect element according to claim 6.

8. A method for manufacturing a magnetization rotation element comprising:
a step of connecting a spin-orbit torque wiring and a first via wiring having a contact region with a higher crystallinity than the spin-orbit torque wiring such that the spin-orbit torque wiring and the contact region come into contact with each other; and
a step of heating the spin-orbit torque wiring and the first via wiring.

9. The method for manufacturing a magnetization rotation element according to claim 8,
wherein a heating temperature is 200° C. or higher.
